(19) United States
(12) Patent Application Publication
(10) Pub. No.: US 2025/0164556 A1
(43) Pub. Date: May 22, 2025

(54) METHOD AND DEVICE OF MANUFACTURING SEMICONDUCTOR DEVICE

(71) Applicant: DENSO CORPORATION, Kariya-city (JP)

(72) Inventors: Tomoo MORINO, Kariya-city (JP); Masayuki IWATSUKI, Kariya-city (JP)

(21) Appl. No.: 19/027,930

(22) Filed: Jan. 17, 2025

Related U.S. Application Data
(63) Continuation of application No. PCT/JP2023/035258, filed on Sep. 27, 2023.

(30) Foreign Application Priority Data
Oct. 10, 2022 (JP) JP2022-162850

(51) Int. Cl. G01R 31/3183; G01R 31/317; G06F 11/263

(52) U.S. Cl. CPC G01R 31/318342; G01R 31/31707; G06F 11/263

(57) ABSTRACT

A method of manufacturing a semiconductor device includes: using a semiconductor element to be inspected as a first semiconductor element; using a semiconductor element for obtaining teaching data as a second semiconductor element; obtaining teaching data including a plurality of data related to characteristics of the second semiconductor element; creating a trained model using the teaching data; and determining whether to perform electric test of the first semiconductor element based on an output obtained by inputting a plurality of data related to characteristics of the first semiconductor element into the trained model.

### CROSS REFERENCE TO RELATED APPLICATION

The present application is a continuation application of International Patent Application No. PCT/JP2023/035258 filed on Sep. 27, 2023, which designated the U.S. and claims the benefit of priority from Japanese Patent Application No. 2022-162850 filed on Oct. 10, 2022. The entire disclosures of all of the above applications are incorporated herein by reference.

### TECHNICAL FIELD

The present disclosure relates to a method and a device of manufacturing a semiconductor device.

### BACKGROUND

Before shipment of a semiconductor device including a MOSFET element, a switching test and a withstand voltage test are performed by applying a high voltage. If an element is broken down by a short circuit during the test, a foreign object may adhere to a jig of the chip tester.

### SUMMARY

According to one aspect of the present disclosure, a method of manufacturing a semiconductor device includes: using a semiconductor element to be inspected as a first semiconductor element; using a semiconductor element for obtaining teaching data as a second semiconductor element; acquiring teaching data including a plurality of data related to characteristics of the second semiconductor element; creating a trained model using the teaching data; and determining whether to perform electric test of the first semiconductor element based on an output obtained by inputting a plurality of data related to characteristics of the first semiconductor element into the trained model.

### BRIEF DESCRIPTION OF DRAWINGS

FIG. 1 is a diagram showing an inspection device according to a first embodiment.

FIG. 2 is a circuit diagram of an inspection circuit.

FIG. 3 is a flowchart of a manufacturing process of a semiconductor device.

FIG. 4 is a diagram showing a breakdown voltage of a semiconductor element.

FIG. 5 is a diagram showing a threshold voltage of a semiconductor element.

FIG. 6 is a flowchart of a manufacturing process of a semiconductor device according to a second embodiment.

FIG. 7 is a flowchart of a high voltage test.

FIG. 8 shows a waveform of a drain current in a high voltage test.

FIG. 9 shows a waveform of a gate-source voltage in a high voltage test.

FIG. 10 shows a waveform of a drain-source voltage in a high voltage test.

### DETAILED DESCRIPTION

Before shipment of a semiconductor device including a MOSFET element, a switching test or a withstand voltage test is performed by applying a high voltage. If an element is broken down by a short circuit during the test, a foreign object adheres to a jig such as probe, stage or collet of the chip tester. If the test is continued in this state, frequent measurement failures and appearance defects are generated due to damage to subsequent chips. Therefore, if an element is destroyed, the jig is replaced to avoid damage to the subsequent chips. When the jig is replaced, the chip cost is increased due to reduced throughput and jig costs. Therefore, if the element is destroyed by a short circuit, the overcurrent is detected and the current is cut off, thereby protecting the jig. For example, if the drain current increases abruptly due to breakdown of a MOSFET element and exceeds a reference value, the current supply to the element is cut off, and the drain current is stopped.

However, with this method, since a large current flows before the current is cut off, it is difficult to reduce the adhesion of foreign matter to the jig due to element destruction.

Regarding the manufacture of semiconductor devices, it is determined whether or not a burn-in test is required for each lot. The burn-in test is performed for a lot determined to require a burn-in test, before the final test process. The necessity of a burn-in test is judged based on a set of criteria, which are determined by conducting a probe test and a burn-in test on multiple chips in advance. Specifically, among test items of the probe test, those that are highly related to the burn-in test results are selected. The inspection results of each chip for this test item are plotted as point data on a two-dimensional graph, and a set of criteria is fixed based on the distribution of the point data.

For example, by screening out defective chips through a burn-in test prior to an electric test, it is possible to restrict element destruction during the electric test and to protect the jig. However, since the test results are converted into one point data per chip, there is a lot of information loss. As a result, sufficient determination accuracy cannot be obtained, and there may be an element destruction.

The present disclosure provides a method and a device of manufacturing a semiconductor device to suppress damage to a semiconductor element.

According to one aspect of the present disclosure, a method of manufacturing a semiconductor device includes: using a semiconductor element to be inspected as a first semiconductor element; using a semiconductor element for obtaining teaching data as a second semiconductor element; acquiring teaching data including a plurality of data related to characteristics of the second semiconductor element; creating a trained model using the teaching data; and determining whether to perform electric test of the first semiconductor element based on an output obtained by inputting a plurality of data related to characteristics of the first semiconductor element into the trained model.

Accordingly, multiple data regarding the characteristics of the second semiconductor element are included in the teaching data, and a determination is made using the multiple data regarding the characteristics of the first semiconductor element. Thus, the determination accuracy is improved and it is possible to suppress damage to the semiconductor element.

According to another aspect, a device of manufacturing a semiconductor device includes a controller configured to determine whether to perform electric test of a semiconductor element based on an output obtained by inputting a plurality of data relating to characteristics of the semiconductor element into a trained model.

Accordingly, since the determination is made using a plurality of data relating to the characteristics of the semiconductor element, the determination accuracy is improved and damage to the semiconductor element can be suppressed.

Hereinafter, embodiments of the present disclosure will be described with reference to the drawings. In the following embodiments, the same reference numerals are assigned to parts that are the same or equivalent to each other to describe the same.

### First Embodiment

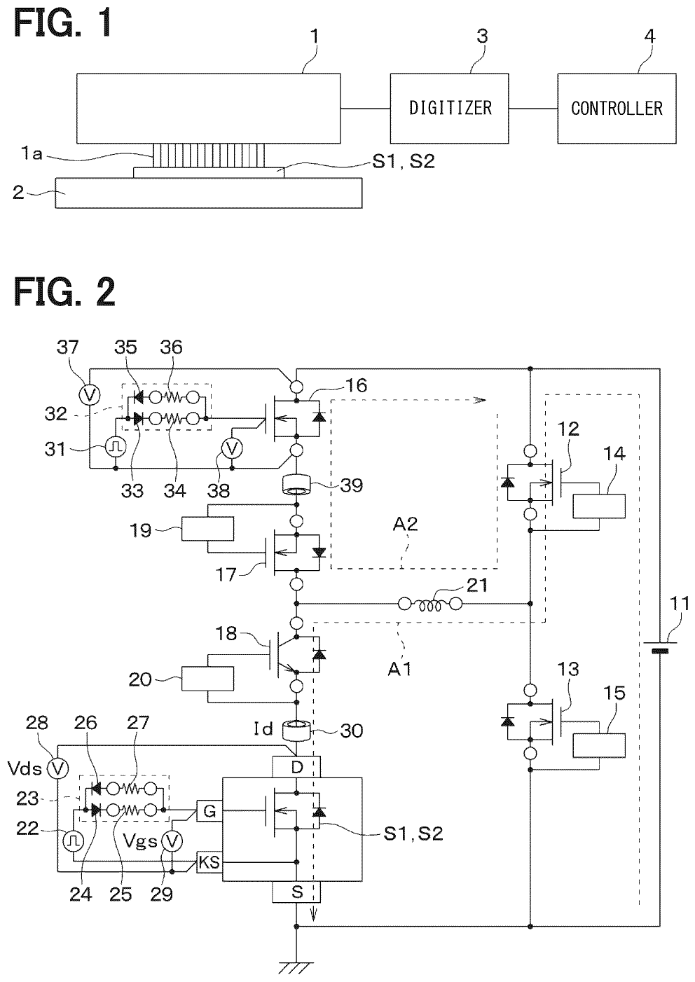

A first embodiment is described below. A device of manufacturing a semiconductor device includes an inspection device shown in FIG. 1. The inspection device includes a chip tester 1, a stage 2, a digitizer 3, and a controller 4.

The chip tester 1 applies a voltage to a semiconductor element S1 to be inspected, and measures the voltage, current, etc. output from the semiconductor element S1. The semiconductor element S1 of this embodiment is a MOSFET element formed as a chip, and is used in an inverter or the like for a vehicle. The semiconductor element S1 corresponds to a first semiconductor element.

As shown in FIG. 1, the semiconductor element S1 is placed on the upper surface of the stage 2. An upper surface of the semiconductor element S1 is connected to the chip tester 1 by plural probes 1a provided on the chip tester 1. The chip tester 1 applies a voltage to the semiconductor element S1 via the probes 1a and measures the output of the semiconductor element S1.

The voltage and current measured by the chip tester 1 are input to the digitizer 3. The digitizer 3 converts the input signal into a digital signal and transmits the digital signal to the controller 4.

The controller 4 controls the chip tester 1 based on data transmitted from the chip tester 1 via the digitizer 3. The controller 4 is configured by a microcomputer or the like including a CPU (not illustrated), a storage unit configured by a non-transitory tangible storage medium such as a ROM, a RAM, a flash memory, or an HDD. CPU is an abbreviation for Central Processing Unit. ROM is an abbreviation for Read Only Memory. RAM is an abbreviation for Random Access Memory. HDD is an abbreviation for Hard Disk Drive.

The controller 4 stores a trained model created in step S102 described later, and controls the chip tester 1 based on the output obtained by inputting the data transmitted from the chip tester 1 into the trained model.

Plural circuit elements are arranged inside the chip tester 1. When the probe 1a is made in contact with the semiconductor element S1, the semiconductor element S1 and the circuit elements arranged inside the chip tester 1 form an inspection circuit as shown in FIG. 2.

In the inspection circuit, a MOSFET element 12 and a MOSFET element 13 are connected to a power source 11. Specifically, the drain electrode of the MOSFET element 12 is connected to the positive electrode of the power source 11. The source electrode is connected to the drain electrode of the MOSFET element 13. The source electrode of the MOSFET element 13 is grounded. The MOSFET element 12 is switched on and off by voltage supplied to the gate electrode from the power source 14. The MOSFET element 13 is switched on and off by voltage supplied to the gate electrode from the power source 15.

A MOSFET element 16, a MOSFET element 17, an IGBT element 18, and the semiconductor element S1 are connected in series between the positive and negative electrodes of the power source 11. Specifically, the drain electrode of the MOSFET element 16 is connected to the positive electrode of the power source 11, and the source electrode is connected to the source electrode of the MOSFET element 17. A drain electrode of the MOSFET element 17 is connected to a collector electrode of the IGBT element 18, and an emitter electrode of the IGBT element 18 is connected to a drain electrode of the semiconductor element S1. The source electrode of the semiconductor element S1 is grounded.

The MOSFET element 17 is switched on and off by voltage supplied to the gate electrode from the power source 19. The IGBT element 18 is switched on and off by voltage supplied to the gate electrode from the power source 20. A connection point between the MOSFET element 12 and the MOSFET element 13 is connected with a connection point between the MOSFET element 17 and the IGBT element 18 via a coil 21.

The semiconductor element S1 has a Kelvin source electrode in addition to the drain electrode, the gate electrode, and the source electrode. The power source 22 that applies a gate voltage to the semiconductor element S1 is disposed between the gate electrode and the Kelvin source electrode of the semiconductor element S1.

A gate drive circuit 23 is disposed between the power source 22 and the gate electrode of the semiconductor element S1. The gate drive circuit 23 is composed of a diode 24, a resistor 25, and a diode 26 and a resistor 27 connected in parallel to the diode 24 and the resistor 25. The diode 24 has an anode electrode connected to the power source 22, and the diode 26 has a cathode electrode connected to the power source 22.

A voltmeter 28 is disposed between the drain electrode and the Kelvin source electrode of the semiconductor element S1. A voltmeter 29 is disposed between the gate electrode and the Kelvin source electrode of the semiconductor element S1. The voltmeter 28 and the voltmeter 29 measure the drain-source voltage Vds and the gate-source voltage Vgs of the semiconductor element S1 respectively.

An ammeter 30 is disposed between the IGBT element 18 and the semiconductor element S1. The ammeter 30 measures the drain current Id of the semiconductor element S1. The measurement results of the drain-source voltage Vds, the gate-source voltage Vgs, and the drain current Id by the voltmeter 28, the voltmeter 29, and the ammeter 30 are input to the digitizer 3 and transmitted to the controller 4.

A power source 31 and a gate drive circuit 32 are disposed between the gate electrode and the source electrode of the MOSFET element 16. The gate drive circuit 32 is composed of a diode 33, a resistor 34, and a diode 35 and a resistor 36 connected in parallel to the diode 33 and the resistor 34. The diode 33 has an anode electrode connected to the power source 31, and the diode 35 has a cathode electrode connected to the power source 31.

A voltmeter 37 is disposed between the drain electrode and the source electrode of the MOSFET element 16, and a voltmeter 38 is disposed between the gate electrode and the source electrode of the MOSFET element 16. The voltmeter 37 and the voltmeter 38 measure the drain-source voltage and the gate-source voltage of the MOSFET element 16 respectively. An ammeter 39 is disposed between the MOSFET element 16 and the MOSFET element 17. The ammeter 39 measures the drain current of the MOSFET element 16. The results of measurements of the drain-source voltage, the gate-source voltage, and the drain current of the MOSFET element 16 by the voltmeter 37, voltmeter 38, and ammeter 39 are input to the digitizer 3 and transmitted to the controller 4.

When current is passed through the semiconductor element S1 in this inspection circuit, the output voltages of the power source 14, the power source 19, the power source 20 and the power source 22 are set to a high level, and the MOSFET element 12, the MOSFET element 17, the IGBT element 18 and the semiconductor element S1 are turned on. The output voltages of the power source 15 and the power source 31 are set to a low level, and the MOSFET element 13 and the MOSFET element 16 are set to an off state. As a result, current flows through the path indicated by the arrow A1 in FIG. 2.

In order to cut off the current flowing through the semiconductor element S1 in this state, the output voltage of the power source 20 is set to a low level, and the IGBT element 18 is turned off. As a result, the current flowing through the semiconductor element S1 is cut off, and the current flowing through the coil 21 returns along the path indicated by the arrow A2.

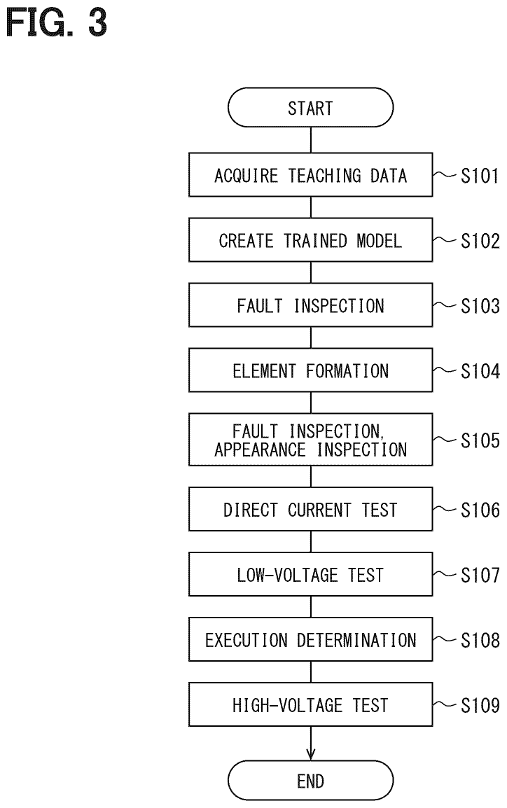

A method of manufacturing a semiconductor device will be described. In this embodiment, the semiconductor device is inspected through steps S101 to S109 shown in FIG. 3.

In step S101, a MOSFET element having the same design as the semiconductor element S1 is prepared as the semiconductor element S2, and teaching data including a plurality of data relating to the characteristics of the semiconductor element S2 is obtained. The semiconductor element S2 is a semiconductor element for acquiring teaching data and corresponds to a second semiconductor element. The semiconductor element S2 is one of a plurality of semiconductor elements S2, and a plurality of data are obtained for each of the semiconductor elements S2.

In this embodiment, waveform data relating to the electrical characteristics of the semiconductor element S2 is used as the multiple data relating to the characteristics of the semiconductor element S2. Specifically, the semiconductor element S2 is subjected to the same inspection as steps S106 and S107 described later using the inspection device shown in FIG. 1. That is, a DC test and a low-voltage AC test are performed on the semiconductor elements S2 to check gate leakage, drain leakage, threshold voltage Vth, on-voltage Von, breakdown voltage, and the like. As a result, waveform data such as Id-Vgs characteristics composed of data on a plurality of points is obtained for each of the semiconductor elements S2.

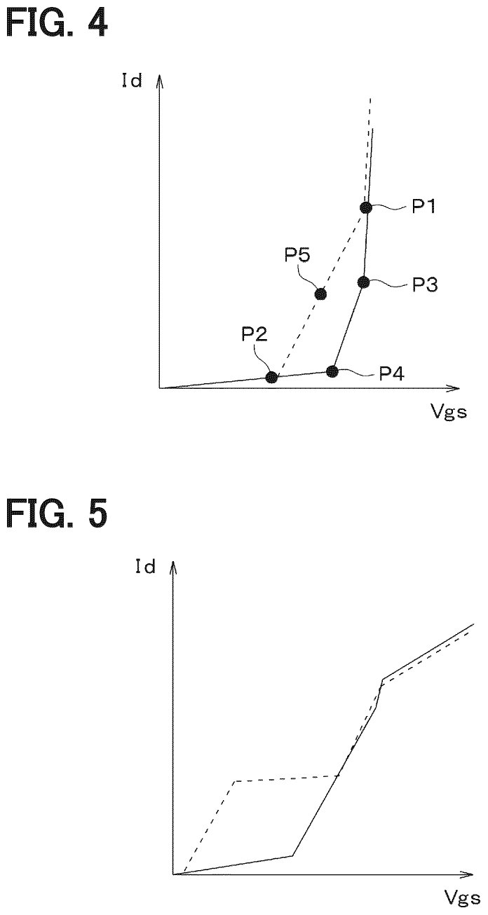

For example, by conducting a withstand voltage test up to about 1200 V on the semiconductor element S2, waveform data of the Id-Vgs characteristics as shown by the solid line or dashed line in FIG. 4 is obtained. Moreover, by changing the gate voltage of the semiconductor element S2 in the range of 0 to 5 V, waveform data of the Id-Vgs characteristics as shown by the solid line or broken line in FIG. 5 is obtained.

After the above inspection, the semiconductor element S2 is subjected to an inspection similar to that in step S109 described later. That is, a high voltage AC test that is more likely to destroy the semiconductor element S2 than the above-mentioned test is performed on the semiconductor element S2. The teaching data includes the test results. In FIGS. 4 and 5, the solid line represents the waveform data of the semiconductor element S2 that was not destroyed in the high voltage test, and the dashed line represents the waveform data of the semiconductor element S2 that was destroyed in the high voltage test.

In step S102, a trained model is created by machine learning using the teaching data acquired in step S101. For example, a trained model can be created using neural networks, deep learning, and the like.

The trained model is created so that a numerical value relating to the possibility of element destruction is output when multiple data relating to the characteristics of the semiconductor element S1 are input. In this embodiment, the plurality of data relating to the characteristics of the semiconductor element S1 are waveform data relating to the electrical characteristics of the semiconductor element S1. For example, a trained model is created so that the probability that the semiconductor element S1 is destroyed in a high voltage AC test, which has a high possibility of element destruction, is output, when inputting waveform data such as Id-Vgs characteristics obtained in an inspection such as a withstand voltage test, which has a low possibility of element destruction of the semiconductor element S1. The controller 4 stores the created trained model.

In step S103, an inspection device (not shown) is used to conduct a fault inspection to inspect the wafer on which the semiconductor element S1 is formed. For example, light is irradiated onto the wafer, and surface and internal defects are detected based on the intensity of the reflected light.

In step S104, the wafer is subjected to a semiconductor process to form MOSFET elements, which are then diced and divided into chip units. As a result, plural chip-shaped semiconductor elements S1 are formed.

In step S105, a fault inspection similar to that in step S103 is performed on the plural semiconductor elements S1. In addition, an appearance inspection is performed on the semiconductor elements S1 to check for cracks or the like.

After step S105, an electric inspection of the semiconductor element S1 is performed. The electric test includes a first electric test and a second electric test that is performed after the first electric test. The second electric test is an inspection in which the semiconductor element S1 is more likely to be destroyed than the first electric test. Specifically, in the second electric test, a voltage higher than that in the first electric test is applied to the semiconductor element S1. In this embodiment, steps S106 and S107 correspond to a first electric test, and step S109 corresponds to a second electric test.

In step S106, a DC test is performed on the semiconductor element S1 using the inspection device shown in FIG. 1. The waveform date such as the gate leak, the drain leak, the threshold voltage Vth, the on-voltage Von or the withstand voltage is obtained and transmitted to the controller 4.

In step S107, an AC test is performed on the semiconductor element S1 using the inspection device shown in FIG. 1, and the waveform date relating to the characteristics of the semiconductor element S1 is obtained and transmitted to the controller 4. The AC test performed in step S107 is a low-voltage switching test or the like.

In step S108, the controller 4 determines whether or not to perform step S109 for the semiconductor element S1 that has been subjected to steps S106 and S107. Specifically, the controller 4 inputs a plurality of data relating to the characteristics of the semiconductor element S1 to be inspected into the trained model created in step S102. As described above, in this embodiment, the multiple data are waveform data related to the electrical characteristics of the semiconductor element S1, and the controller 4 inputs the waveform data acquired in steps S106 and S107 into the learned model. Then, the controller 4 determines, based on the output thus obtained, whether or not to carry out step S109 for this semiconductor element S1. For example, when the numerical value indicating the probability of element destruction output from the trained model is less than a predetermined value, the controller 4 determines to perform step S109. When this numerical value is equal to or greater than the predetermined value, the controller 4 determines not to perform step S109.

In step S109, for the semiconductor element S1 for which it has been determined in step S108 that step S109 should be performed, a high-voltage switching test that is likely to cause element destruction is performed to check the switching resistance, avalanche resistance, and the like.

Thereafter, packaging and the like are carried out for the semiconductor element S1 that has been determined to be a non-defective product in the inspections including steps S103, S105, S106, S107, and S109. In this manner, a semiconductor device including the semiconductor element S1 is manufactured.

The effects of this embodiment are described. If the results of DC test or the like performed on the semiconductor elements S2 are converted into one point data per semiconductor element S2 to create the teaching data, there will be a lot of missing information, and sufficient determination accuracy will not be obtained in step S108. For example, if the data at point P1 or point P2 in FIG. 4 is selected when acquiring teaching data, the difference in data value between the semiconductor element S2 in which element destruction has occurred and the semiconductor element S2 in which element destruction has not occurred becomes small. Therefore, it becomes difficult for the trained model to reflect the difference between the two types of data, and the accuracy of determination decreases.

In contrast to this, in this embodiment, the teaching data is created to include the waveform data of FIG. 4. According to this, in addition to points P1 and P2 in FIG. 4, the teaching data includes data for points P3, P4, and P5, where differences are clear between the two waveforms, making it easier for the difference between the two types of data to be reflected in the trained model, improving the accuracy of determination.

As described above, in this embodiment, a plurality of data relating to the characteristics of the semiconductor element S2 is included in the teaching data, and a determination as to whether or not to perform a high voltage test is made using a plurality of data relating to the characteristics of the semiconductor element S1. Therefore, the accuracy of the determination is improved, and damage to the semiconductor element S1 can be suppressed. This makes it possible to suppress damage to jig such as the probe 1a due to element destruction and adhesion of foreign matter, and to reduce increases in chip costs due to reduced throughput and increased jig costs.

### Second Embodiment

A second embodiment is described. In this embodiment, the timing of determining whether or not to perform an electric test is changed from that in the first embodiment, but other points are the same as in the first embodiment, so only the points that are different from the first embodiment will be described.

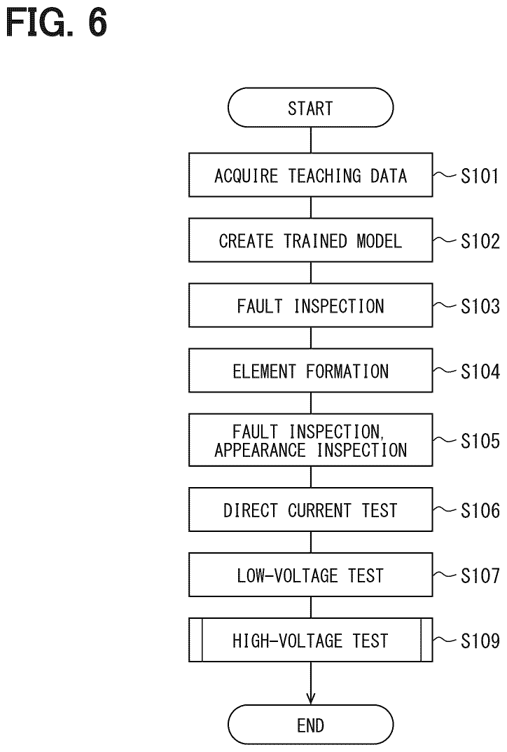

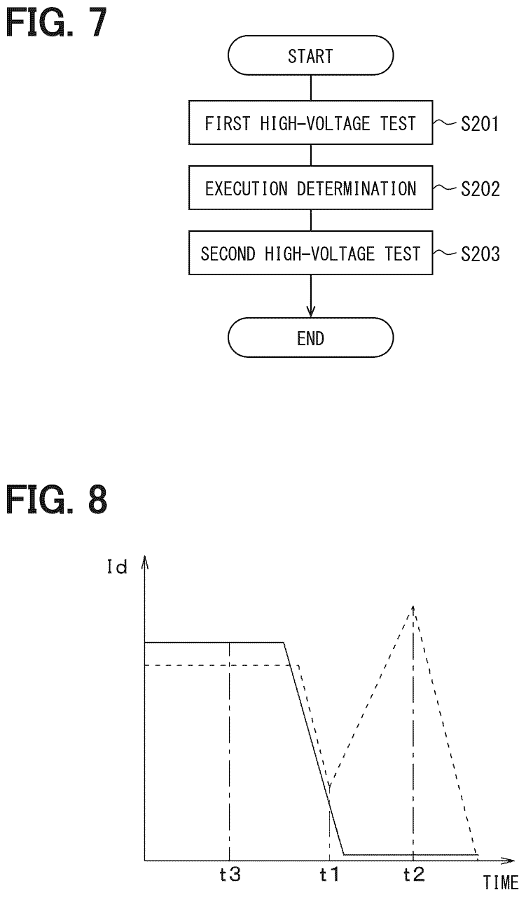

In this embodiment, the determination as to whether or not to perform the electric test is made at a midpoint of the second electric test. Specifically, as shown in FIG. 6, after step S107, step S109 is started without performing step S108. Then, in step S109, steps S201 to S203 are carried out in order as shown in FIG. 7.

In step S101 of this embodiment, the inspection device shown in FIG. 1 is used to perform a high voltage test on the semiconductor elements S2 similar to step S109 of the first embodiment. Then, waveform data of the drain current Id, the gate-source voltage Vgs, and the drain-source voltage Vds as shown in FIGS. 8 to 10 is obtained. Also, data on whether or not the element is destroyed by the high voltage test and data on the time until the element is destroyed are obtained.

In FIGS. 8 to 10, the solid line shows waveform data of the semiconductor element S2 that was not destroyed in the high voltage test, and the dashed line shows waveform data of the semiconductor element S2 that was destroyed in the high voltage test. In FIGS. 8 to 10, the element is broken down when time t1 has elapsed from the start of the test, and the drain current Id increases sharply. Then, when time t2 has elapsed from the start of the test, the drain current Id reaches or exceeds a predetermined value, and the IGBT element 18 in FIG. 2 is turned off. Thus, the current flowing through the semiconductor element S2 is cut off, and the drain current Id decreases.

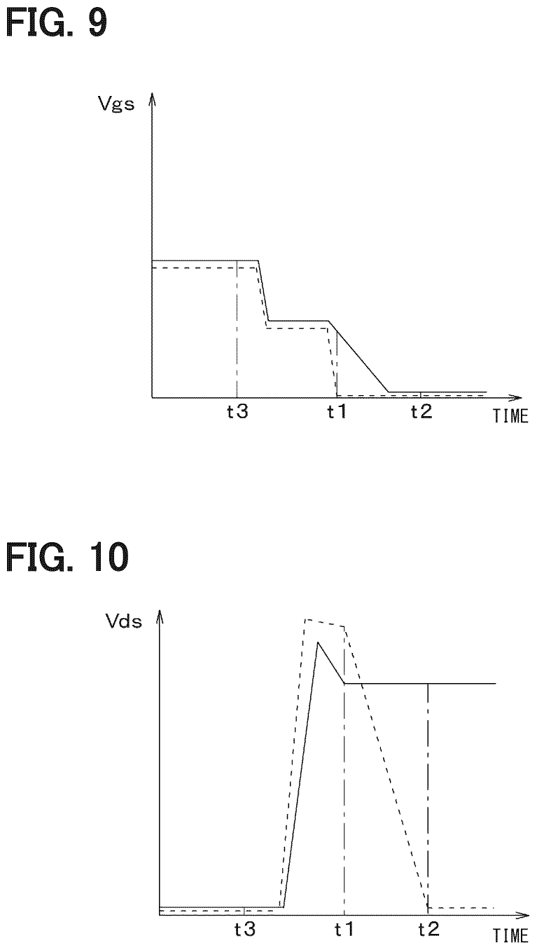

As shown in FIGS. 8 and 9, the waveform data of the semiconductor element S2 that was destroyed in the high voltage test has smaller values of the drain current Id and the gate-source voltage Vgs immediately after the start of the test than the waveform data of the semiconductor element S2 that was not destroyed. This is believed to be because, for example, cracks began to form in the gate oxide film after the start of the test, causing the effective gate voltage to decrease.

In step S102, a trained model is created by machine learning using teaching data including the data acquired in step S101. The trained model is created to output the probability that the semiconductor element S1 will be destroyed if the high voltage test is continued, when inputting the waveform data in the high voltage test of the semiconductor element S1.

In step S201, a high voltage test is performed on the semiconductor element S1. In step S201, the test is completed in a shorter time than in step S109 in the first embodiment. The time t3 until the end of the test is set to be shorter than the time t1 at which the semiconductor element S2 is destroyed in step S101. In step S201, the digitizer 3 transmits waveform data of the drain-source voltage Vds, the gate-source voltage Vgs, and the drain current Id during the high voltage test to the controller 4.

In step S202, the controller 4 determines, based on the waveform data transmitted from the digitizer 3, whether or not to perform step S203 for the semiconductor element S1 on which step S201 has been performed. Specifically, the controller 4 inputs the waveform data acquired in step S201 for the semiconductor element S1 to be inspected into the trained model created in step S102. Then, the controller 4 determines, based on the output thus obtained, whether or not to carry out step S203 for this semiconductor element S1. For example, when the numerical value indicating the probability of element destruction output from the trained model is less than a predetermined value, the controller 4 determines to perform step S203. When this numerical value is equal to or greater than the predetermined value, the controller 4 determines not to perform step S203.

In step S203, the high voltage test is continued for the semiconductor element S1 for which it has been determined in step S202 that step S203 should be performed.

The present embodiment can achieve the same effects as those of the first embodiment from the same configuration and operation as those of the first embodiment.

### Other Embodiments

The present disclosure is not limited to the above-described embodiments, and can be appropriately modified. Individual elements or features of a particular embodiment are not necessarily essential unless it is specifically stated that the elements or the features are essential in the foregoing description, or unless the elements or the features are obviously essential in principle. A quantity, a value, an amount, a range, or the like referred to in the description of the embodiments described above is not necessarily limited to such a specific value, amount, range or the like unless it is specifically described as essential or understood as being essential in principle.

A determination as to whether an electric test should be performed may be made in a WAT (Wafer Acceptance Test) or package inspection in the same manner as in the first and second embodiments. This makes it possible to suppress damage to the jig that would otherwise be caused by destruction of the wafer or package.

In the second embodiment, step S108 may be performed as in the first embodiment. That is, step S108 may be performed after step S107. Steps S201 and S202 may be performed for the semiconductor element S1 for which it has been determined that step S109 should be performed, and step S203 may be performed for the semiconductor element S1 for which it has been determined that step S203 should be performed. In this case, in step S101, the semiconductor element S2 is subjected to an inspection similar to that in steps S106 and S107, and teaching data including data obtained thereby is created. Then, in step S102, a trained model is created to input the data obtained in steps S106 and S107 for the semiconductor element S1, and a trained model is created to input the data obtained in step S201, and these are used for determination in steps S108 and S202.

Furthermore, steps S101 and S102 may be performed at different timings from those in the first and second embodiments. For example, steps S101 and S102 may be performed after steps S103 to S105.

Moreover, image data of the semiconductor element S1, S2 may be used as the plurality of data relating to the characteristics of the semiconductor element S1, S2. For example, a trained model may be created using teaching data including image data obtained in a fault inspection of the semiconductor element S2, and in step S108, image data obtained in a fault inspection of the semiconductor element S1 may be input into the trained model to determine whether or not to carry out step S109. In addition, a trained model may be created using teaching data including image data obtained by appearance inspection of the semiconductor element S2, and in step S108, image data obtained by appearance inspection of the semiconductor element S1 may be input into the trained model to determine whether to implement step S109. When image data is used, the multiple data related to the characteristics of the semiconductor element S1, S2 may include both waveform data related to the electrical characteristics of the semiconductor element S1, S2 and image data, or only image data may be used without using waveform data. Furthermore, when image data is used, both image data obtained by fault inspection and image data obtained by appearance inspection may be used. The plurality of data relating to the characteristics of the semiconductor element S1, S2 may include data other than the waveform data and image data described above.

Furthermore, for the semiconductor element S1 for which it is determined in steps S108 and S202 that steps S109 and S203 are not to be performed, tests similar to those in steps S109 and S203 may be performed, and the data obtained thereby may be included in the teaching data. That is, it may be possible to check whether the semiconductor element S1 determined to have a high possibility of element destruction will actually be destroyed in the high voltage test, and to reflect the result in the teaching data. This can further improve the accuracy of the determination in steps S108 and S202.

The controller and the method described in the present disclosure may be implemented by a special purpose computer which is configured with a memory and a processor programmed to execute one or more particular functions embodied in computer programs of the memory. Alternatively, the controller and the method described in the present disclosure may be implemented by a special purpose computer configured as a processor with one or more special purpose hardware logic circuits. Alternatively, the controller and the method described in the present disclosure may be implemented by one or more special purpose computer, which is configured as a combination of a processor and a memory, which are programmed to perform one or more functions, and a processor which is configured with one or more hardware logic circuits. The computer programs may be stored, as instructions to be executed by a computer, in a tangible non-transitory computer-readable medium.

What is claimed is:

1. A method of manufacturing a semiconductor device comprising:
using a semiconductor element to be inspected as a first semiconductor element;
using a semiconductor element for acquiring teaching data as a second semiconductor element;
acquiring the teaching data including a plurality of data related to characteristics of the second semiconductor element;
creating a trained model using the teaching data; and
determining whether to perform an electric test of the first semiconductor element based on an output obtained by inputting a plurality of data related to characteristics of the first semiconductor element into the trained model.

2. The method according to claim 1, wherein
the plurality of data related to the characteristics of the first semiconductor element include waveform data relating to electrical characteristics of the first semiconductor element, and
the plurality of data related to the characteristics of the second semiconductor element include waveform data relating to electrical characteristics of the second semiconductor element.

3. The method according to claim 1, wherein
the electric test includes a first electric test and a second electric test performed after the first electric test,
the teaching data includes data obtained in the first electric test of the second semiconductor element, and
the determining includes determining whether to perform the second electric test based on an output obtained by inputting data obtained in the first electric test of the first semiconductor element into the trained model.

4. The method according to claim 1, wherein
the electric test includes a first electric test and a second electric test performed after the first electric test, a voltage higher than that of the first electric test being applied in the second electric test,
the teaching data includes data obtained in the second electric test of the second semiconductor element,
the determining whether to perform the electric test is conducted at a midpoint of the second electric test, and
the determining includes determining whether to continue performing the second electric test based on an output obtained by inputting data up to a midpoint of the second electric test of the first semiconductor element into the trained model.

5. The method according to claim 1, wherein
the electric test includes a first electric test and a second electric test performed after the first electric test, a voltage higher than that of the first electric test being applied in the second electric test,
the teaching data includes data obtained in the first electric test of the second semiconductor element and data obtained in the second electric test,
the determining whether to perform the electric test is conducted before the second electric test and at a midpoint of the second electric test,
the determining whether to perform the electric test before the second electric test includes determining whether to perform the second electric test based on an output obtained by inputting data obtained in the first electric test of the first semiconductor element into the trained model, and
the determining whether to perform the electric test at the midpoint of the second electric test includes determining whether to continue performing the second electric test based on an output obtained by inputting data obtained up to the midpoint of the second electric test of the first semiconductor element into the trained model.

6. The method according to claim 1, wherein
the plurality of data related to the characteristics of the first semiconductor element include image data of the first semiconductor element, and
the plurality of data related to the characteristics of the second semiconductor element include image data of the second semiconductor element.

7. The method according to claim 1, wherein
the teaching data includes data obtained by a fault inspection of the second semiconductor element, and
determining whether to perform the electric test includes inputting data obtained in the fault inspection of the first semiconductor element into the trained model.

8. The method according to claim 1, wherein
the teaching data includes data obtained by an appearance inspection of the second semiconductor element, and
determining whether to perform the electric test includes inputting data obtained in the appearance inspection of the first semiconductor element into the trained model.

9. The method according to claim 1, wherein the teaching data includes data obtained by conducting a test similar to the electric test on the first semiconductor element for which it has been determined that the electric test should not be performed.

10. A device of manufacturing a semiconductor device comprising:
a processor and memory configured to determine whether to perform electric test of a semiconductor element based on an output obtained by inputting a plurality of data relating to characteristics of the semiconductor element into a trained model.

11. The device according to claim 10, wherein the plurality of data related to the characteristics of the semiconductor element include waveform data relating to electrical characteristics of the semiconductor element.

12. The device according to claim 10, wherein
the electric test includes a first electric test and a second electric test performed after the first electric test, and
the processor and memory determine whether to perform the second electric test based on an output obtained by inputting data obtained in the first electric test of the semiconductor element into the trained model.

13. The device according to claim 10, wherein
the electric test includes a first electric test and a second electric test performed after the first electric test, a voltage higher than that of the first electric test being applied in the second electric test, and
the processor and memory determine whether to continue performing the second electric test based on an output obtained by inputting data obtained up to a midpoint point of the second electric test of the semiconductor element into the trained model.

14. The device according to claim 10, wherein
the electric test includes a first electric test and a second electric test performed after the first electric test, a voltage higher than that of the first electric test being applied in the second electric test,
the processor and memory determine whether to perform the second electric test based on an output obtained by inputting data obtained in the first electric test of the semiconductor device into the trained model, and
the processor and memory determine whether to continue the second electric test based on an output obtained by inputting data obtained at a midpoint of the second electric test of the semiconductor element into the trained model.

15. The device according to claim 10, wherein the plurality of data related to the characteristics of the semiconductor element include image data of the semiconductor element.

16. The device according to claim 10, wherein the processor and memory input data obtained by a fault inspection of the semiconductor element into the trained model.

17. The device according to claim 10, wherein the processor and memory input data obtained by an appearance inspection of the semiconductor element into the trained model.
